(19) United States
(12) Patent Application Publication
(10) Pub. No.: US 2013/0210543 A1
(43) Pub. Date: Aug. 15, 2013

(54) GOLF CLUB HEAD

(71) Applicants: Nathaniel J. RADCLIFFE, Huntington Beach, CA (US); Manny WANG, Irvine, CA (US); Samuel G. LACEY, Park City, UT (US)

(72) Inventors: Nathaniel J. RADCLIFFE, Huntington Beach, CA (US); Manny WANG, Irvine, CA (US); Samuel G. LACEY, Park City, UT (US)

(73) Assignee: SRI SPORTS LIMITED, Kobe-shi (JP)

(21) Appl. No.: 13/369,792

(22) Filed: Feb. 9, 2012

(51) Int. Cl. A63B 53/04; C23C 14/34; C23C 28/00; C23C 14/06; C23C 14/14

(52) U.S. Cl. 473/345; 473/349; 427/250; 427/249.1; 205/191; 204/192.1

(57) ABSTRACT

A golf club head is manufactured so as to be at least partially composed of martensitic stainless steel and to have an exterior surface. At least one chromium layer is deposited on at least a portion of the exterior surface of the golf club head. At least one outer layer is deposited by physical vapor deposition on at least a portion of the at least one chromium layer, the outer layer including a metal and a nonmetal.

The disclosure below may be subject to copyright protection. The copyright owner has no objection to the facsimile reproduction by anyone of the documents containing this disclosure, as they appear in the Patent and Trademark Office records, but otherwise reserves all applicable copyrights.

### BACKGROUND

Golf club heads are conventionally designed to withstand wear caused by impact with a golf ball during use, abrasion with turf, and general exposure to environmental elements. Accordingly, conventional club heads are typically formed of a main body having a material composition and, in some cases, a coating application or surface treatment directed at improving performance and wear resistance. For example, some conventional club heads have main bodies formed of relatively rust-resistant materials, such as titanium or various stainless steels, particularly stainless steels having high chromium content and/or a martensitic crystalline structure. In addition to such base materials, surface treatments and/or coating applications are desirable to further improve performance, wear resistance and appearance. For example, some conventional club heads include portions that have been work-hardened, tempered, anodized, chemically etched, electroplated, etc. Coatings applied by ion deposition or physical vapor deposition, e.g. titanium carbide or titanium nitride, are particularly advantageous for their durability and appearance. Physical vapor deposition also provides for a relatively easy and cost-efficient coating application.

Nonetheless, conventional club heads, as they may be coated, fail to account for the performance and appearance of the club head once an outermost coating inevitably wears or begins to breach. Despite advances in coating technology, external surfaces of club heads ultimately wear over use. For examples, scratches and nicks ultimately breach even the most durable external surfaces, exposing underlying surfaces. Even where oxidation is not a concern, such exposure of underlying surfaces may result in a dull, lackluster finish. This manner of wear significantly affects the confidence of the golfer and effects a perception that the club head has prematurely deteriorated or is inferior in quality.

### SUMMARY

Over time and through use or handling, the bottom portion or other portions of the golf club head may show scratches, nicks, or abrasions on the exterior surface of the golf club head. For example, when striking a golf ball with a striking face of a golf club head, the bottom portion (or sole) of the golf club head can be scratched, nicked, or abraded by its contact with the ground surface. This is of particular importance with respect to wood type club heads as they generally contact the turf with significantly larger force. This is of even greater importance with regard to fairway woods, which are adapted to contact a golf ball directly on turf.

These scratches, nicks, or abrasions tend to remove one or more outer layers of the golf club head and expose the underlying material. When the outer layer of the golf club head has been colored for aesthetic or glare reducing purposes, the exposed underlying material is especially visible to the golfer, and thus does not inspire confidence in the golfer as to the quality of manufacture and/or performance capabilities of the golf club head. A golfer's lack of confidence with respect to the quality of manufacture and/or performance capabilities of the golf club head negatively affects his or her skill and/or accuracy.

The present inventors have discovered that a layer of chromium under a colored outer layer has the unexpected effect of making any scratches, nicks, or abrasions less visible to a golfer. This result is unexpected because the conventional wisdom is that a reflective material would be more visible against a colored background. However, it is believed that a reflective material such as chromium makes scratches, nicks, and abrasions less visible because the reflective exposed chromium reflects the color of the outer layer surrounding the scratches, nicks, and abrasions. Furthermore, when large areas of chromium become exposed, it has been determined that the reflective nature of the exposed chromium leaves the golfer with the impression that the club head is composed of quality materials compared to exposed less reflective materials such as steel, titanium, or nickel. The impression that a club head is composed of quality materials helps to inspire confidence in the golfer rather than reduce confidence.

In U.S. Patent Application Publication No. 2008/0287215 (hereinafter “Application '215”), a golf club head is described as having a base material of a ferrous material, particularly an iron alloy, such as stainless steel, or a non-ferrous material, such as titanium or a titanium alloy. According to Application '215, these materials require the application of a layer of material (i.e., the first layer of nickel or nickel alloy) between the base material and the layer of chromium, chromium alloy, palladium, or palladium alloy in order to prevent rusting of the golf club head or to fill in surface roughness or microporosity resulting from the manufacturing process.

The present inventors have discovered that benefits may be achieved by using martensitic stainless steel as a base material. Such stainless steel does not require the use of a nickel or nickel alloy layer. By avoiding the use of a nickel or nickel alloy layer, the cost and complexity of producing the golf club head are reduced while maintaining all of the desired features of the golf club head. Of course, a layer of nickel or nickel alloy may still be utilized for added protection, if desired.

According to one aspect of the invention, a method of manufacturing a golf club head includes providing a golf club head at least partially composed of martensitic stainless steel and having an exterior surface. The method further includes depositing at least one chromium layer on at least a portion of the exterior surface of the golf club head and physical vapor depositing at least one outer layer on at least a portion of the at least one chromium layer, the outer layer including a metal and a nonmetal.

According to another aspect of the invention, a golf club head includes a main body at least partially composed of martensitic stainless steel and having an exterior surface. The golf club head further includes at least one chromium layer on at least a portion of the exterior surface and at least one physical-vapor-deposited outer layer on at least a portion of the at least one chromium layer, the at least one outer layer including a metal and a nonmetal.

According to yet another aspect of the invention, a golf club head includes a main body at least partially composed of martensitic stainless steel and having an exterior surface. The golf club head further includes at least one physical-vapor-deposited chromium layer on at least a portion of the exterior surface corresponding to a portion of the golf club head that is designed to contact the ground during use of a golf club including the golf club head. The golf club head also includes at least one physical-vapor-deposited outer layer on at least a portion of the at least one chromium layer, the at least one outer layer including at least one of titanium nitride and titanium carbide. The golf club head has a volume greater than or equal to about 120 cm³ but less than or equal to about 220 cm³.

Additional aspects of the invention include one or more of the following. The metal is selected from the group consisting of vanadium, chromium, zirconium, titanium, niobium, molybdenum, hafnium, tantalum, and tungsten, and the nonmetal is selected from the group consisting of a nitride, a carbide, and a carbonitride. The at least one chromium layer is electroplated, sputtered, and/or physical vapor deposited with corresponding resulting structure. The golf club head, or a main body thereof, has a volume greater than or equal to about 80 cm³, greater than or equal to about 120 cm³, or greater than or equal to about 120 cm³ but less than or equal to about 220 cm³. At least one nickel layer is deposited on the exterior surface of the golf club head underneath at least a portion of the at least one chromium layer. The exterior surface of the golf club head includes a top portion and a bottom portion, and the at least one chromium layer is deposited on only the bottom portion of the exterior surface, or on only a part of the bottom portion that is designed to contact the ground during use of a golf club including the golf club head. The at least one outer layer is deposited on only the at least one chromium layer. The at least one outer layer includes at least one of titanium nitride and titanium carbide. The metal and the nonmetal are selected such that the outer layer is a predetermined color selected from the group consisting of black, silver, gray, blue, gold, purple, bronze, white, red, pink, and green. The golf club head is hollow. The golf club head further includes a loft angle no greater than 22 degrees. The martensitic stainless steel has a chromium content no less than 14% by mass.

These and other features and advantages of the golf club head according to the invention in its various aspects, as provided by one or more of the various examples described in detail below, will become apparent after consideration of the ensuing description, the accompanying drawings, and the appended claims. The accompanying drawings are for illustrative purposes only, are not drawn to scale, and are not intended to limit the scope of the present invention.

### BRIEF DESCRIPTION OF THE DRAWINGS

FIG. 1A is a top plan view of an exemplary golf club head according to one or more aspects of the present invention; FIG. 1B is a front elevational view of the exemplary golf club head of FIG. 1A; and FIG. 1C is a partial cross-sectional view taken along line A-A′ of FIG. 1B;

FIG. 2 is an enlarged view of the cross-sectional view of the layered coatings of the golf club head of FIG. 1C according to one or more aspects of the present invention;

FIG. 3 is an enlarged view of the cross-sectional view of the layered coatings of the golf club head of FIG. 1C according to one or more aspects of the present invention; and

FIG. 4 is a flow chart of a process of coating a golf club head according to one or more aspects of the present invention.

### DETAILED DESCRIPTION

Conventional golf club heads comprise a body having a top portion, a bottom portion, and a striking face. The bottom portion, in particular, comes into contact with the ground during a typical golf swing. As a result of the contact with the ground and any other wear associated with golf club usage, the golf club head experiences scratches, nicks, or abrasions on the exterior surface. These scratches, nicks, or abrasions on the exterior surface of the golf club head result in a lack-luster appearance, affecting the golfer's confidence and perception of quality of his or her equipment.

Any portion of the golf club head may be coated with any of a variety of surface coatings. Any such coatings may be durable, performance-enhancing, and/or confidence-inducing finishes, and include any coating that affects the look and/or performance of the golf club head.

The processes by which such coatings can be applied include physical vapor deposition (“PVD”), electroplating, and non-PVD sputtering. PVD is a generic term used to describe a family of coating processes. Generally, there are three basic categories of processes known as PVD processes: ion plating, evaporation, and sputtering. PVD processes are fundamentally vaporization coating processes in which the basic coating mechanism is a transfer of material from the solid phase to the vapor phase and then back to the solid phase. In the vapor phase, a solid material such as a metal is sublimated to form a gas under high temperatures and reduced pressures and subsequently deposited as a solid on the object to be coated. The vapors are transported through a vacuum or partial vacuum by the energy of the vapor particles. Some reactions between the target materials and the reactive gases may take place at the substrate being coated simultaneously with the deposition process. PVD processes are typically conducted at elevated temperatures, that is, above 200° C. and normally between 200° C. and 400° C. and even higher.

Chemical compounds rather than elemental metal coatings may be deposited by introducing a reactive gas in the PVD chamber that reacts with the metal vapor from the PVD source to form the desired coating compound. Examples of such reactive gases include nitrogen, oxygen, or simple hydrocarbons such as acetylene. Using nitrogen as the reactive gas yields coating compounds that are nitrides. Oxygen yields coating compounds that are oxides. Hydrocarbons yield coating compounds that are carbides. Mixtures of nitrogen and hydrocarbons yield carbonitrides. Depending on the metal vapor, the gaseous component, and the respective ratios of each, the colors of the coating material may be varied over a wide range including black, silver, gray, blue, gold, purple, bronze, white, red, pink, and green, for example.

PVD coatings are desirable because they are often harder and more corrosion resistant than coatings applied in other ways, such as by electroplating. PVD coatings conventionally outperform painted coatings with respect to durability. Most PVD coatings have high temperature resistance, good impact strength, and excellent abrasion resistance and durability. When coating a steel object, for example, PVD processes are preferred because the deposition temperature exceeds the austenitizing temperature of steel.

PVD coatings are deposited as highly adhered, pure metal or alloy coatings on the surface of the substrate. The thickness of the coating preferably ranges from between 0.5 to 10 microns (μ), more preferably between 0.5 and 5 microns. The layers can be deposited singly or as multi-layer coatings.

All these characteristics make PVD processes and PVD coatings preferable for use in preparing golf club heads because they provide for improved performance, good appearance, and a confidence-inspiring finish while also decreasing manufacturing cost.

Before beginning any PVD process, the part to be coated should have all burrs removed to prevent exposure of uncoated metal when the burrs are later broken off. The surface of the object to be coated (substrate) should also be thoroughly cleaned because conditions that reduce film adhesion such as the presence of surface oxides, grinding burrs, imbedded polishing compounds, and rust-preventive films inhibit the deposition process and formation of uniform layers of the coating material.

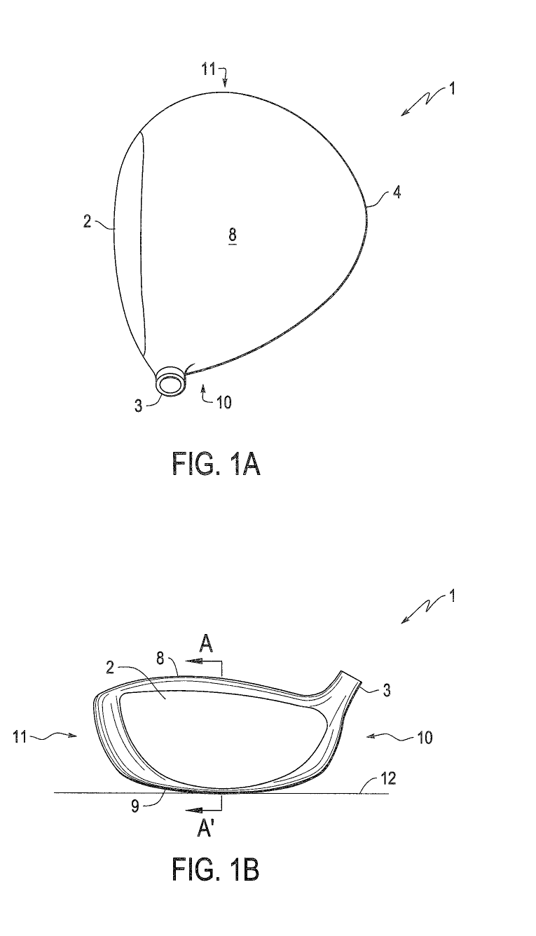

As depicted by way of example in FIGS. 1A-C, a golf club head 1, to which the present invention is applicable, may be a fairway wood golf club head. It is noted, however, that while the golf club head 1 is illustrated as a fairway wood golf club head, the golf club head 1 may be any of, e.g., wood-type, iron-type, putter-type, hybrid-type, etc. It is further noted that while the golf club head 1 is illustrated as being a right-handed golf club head, any reference to any position on the golf club head 1 may be mirrored and applied to a left-handed golf club head.

FIG. 1A depicts a top plan view, FIG. 1B depicts a front elevational view, and FIG. 1C depicts a partial cross-sectional view of a golf club head 1 coated as discussed below according to one or more aspects of the invention. The golf club head comprises a hosel 3, a striking face 2, and a body 4. In this example, the body 4 is a hollow shell 1A, which may include one or more internal reinforcing features (not shown). The body 4 includes a top portion 8, a bottom portion (or sole) 9, a toe portion 11, and a heel portion 10. All or at least a portion of the body 4 may be formed from martensitic stainless steel. The striking face 2 may be formed as part of the body 4 and thus may also be formed from martensitic stainless steel. Alternatively, the striking face 2 may be a separate component of the golf club head 1 and may be made from any suitable material or materials selected from martensitic stainless steel, stainless steel, titanium, titanium alloy, aluminum, copper, polymer, and fiber-reinforced polymer (“FRP”).

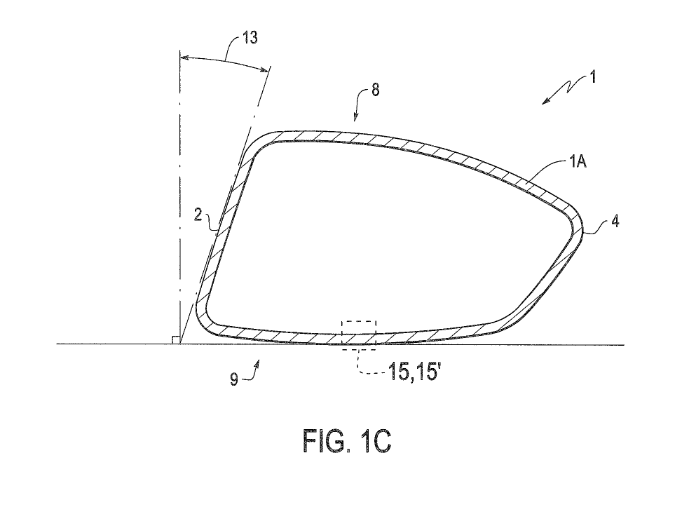

FIG. 2 illustrates area 15 of the FIG. 1C cross-sectional view of one aspect of the shell 1A of the golf club head 1, including a substrate 20 and two layered coatings. According to this aspect of the invention, the substrate 20 is formed of a material chosen from titanium, steel, stainless steel, a polymer, or a fiber-reinforced polymer. Preferably, the substrate 20 is formed of a rust-resistant material such as a martensitic stainless steel, titanium, or a polymer-based material. A layer 5 is a coating applied to all or part of the substrate 20 of the golf club head 1. For example, the layer 5 may be applied only on the bottom portion 9, or a part thereof, of the body 4. The layer 5 may be chromium or a chromium alloy that is applied to the exterior surface of the golf club head 1, or some portion of the exterior surface of the golf club head 1, by electroplating, non-PVD sputtering, or PVD, or another coating process that allows for the adherence of the layer 5 to the exterior surface of the golf club head 1. Preferably, the layer 5 comprises a thickness less than about 0.20 μm. More preferably, the thickness of the layer 5 is between about 0.04 μm and about 0.15 μm. Even more preferably, the layer 5 is between about 0.07 μm and about 0.12 μm. Such ranges ensure that the coating 5 is sufficiently durable to withstand typical abrasion over the desired life of the club head 1, yet cost-effective to produce.

As discussed above, when the golf club head 1 comes into contact with the ground 12 (FIG. 1B), the golf club head 1 is likely to develop scratches, nicks, and/or abrasions due to the force with which the golf club head 1 contacts the ground 12 as well as due to the friction that results in this contact. Thus, when an outer layer 6, discussed below, is abraded, scratched, and/or nicked due to this contact, the layer 5, disposed beneath at least the portion of the outer layer 6 that comes into contact with the ground 12, shows through the outer layer 6. The appearance of the layer 5 in the portions of the outer layer 6 that have been nicked, scratched, and/or abraded allows for an appealing appearance of the golf club head 1, even in light of the nicks, scratches, and/or abrasions. Thus, the layer 5 may be deposited on only a part of the bottom portion 9 of the golf club head 1 that is designed to contact the ground 12 during use of a golf club including the golf club head 1.

According to this aspect, an outer layer 6 is a coating applied to all or part of the golf club head 1, including or excluding portions including the layer 5. For example, the outer layer 6 may be applied to the entire exterior surface of the golf club head 1, the entire portion of the golf club head 1 that is coated with the layer 5, a portion of the golf club head 1 that is coated with the layer 5, and/or a portion of the exterior surface of the golf club head 1 that is not coated with the layer 5. The outer layer 6 may be applied by electroplating or non-PVD sputtering. Preferably, however, the outer layer 6 is applied by PVD.

The outer layer 6 may comprise a metal and a nonmetal. The metal of the outer layer 6 is preferably a metal chosen from the group consisting of vanadium, chromium, zirconium, titanium, niobium, molybdenum, hafnium, tantalum, and tungsten. The nonmetal of the outer layer 6 is preferably a nonmetal chosen from the group consisting of nitride, carbide, and carbonitride. The various possible combinations of the different metals and nonmetals to produce the outer layer 6 can result in different color options for the outer layer 6 such as black, silver, gray, blue, gold, purple, bronze, white, red, pink, and green. For example, titanium nitride, low-temperature titanium nitride, and zirconium nitride result in the outer layer 6 having a gold color, titanium carbonitride results in the outer layer 6 having a purple color, aluminum titanium nitride or titanium carbide results in the outer layer 6 having a black color, and chromium nitride results in the outer layer 6 having a silver/gray color. The outer layer is preferably composed of at least one of titanium nitride and titanium carbide.

As discussed above, the golf club head shell 1A is at least partially composed of martensitic stainless steel. The martensitic stainless steel may include a chromium content of no less than 14% by mass. The use of the martensitic stainless steel prevents or minimizes the rusting or oxidation of the golf club head. Due to the use of the martensitic stainless steel, it is unnecessary to utilize another layer beneath the layer 5 in order to prevent rusting of the golf club head 1.

According to various aspects of the invention, the golf club head 1 is a fairway wood having a volume greater than or equal to about 80 cm³, preferably greater than or equal to about 120 cm³, and more preferably greater than or equal to about 120 cm³ but less than or equal to about 220 cm³. The golf club head is preferably hollow and may have a loft angle 13 (FIG. 1C) no greater than 22 degrees, preferably between 12 degrees and 22 degrees.

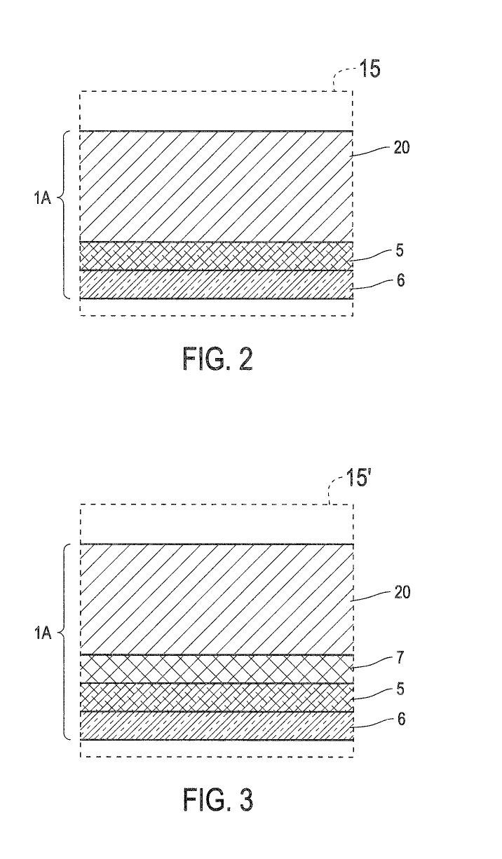

FIG. 3 illustrates area 15′ of the FIG. 1C cross-sectional view of another aspect of the shell 1A of the golf club head 1, including three layered coatings. According to this aspect of the invention, a base layer 7 is a coating applied to all or part of the exterior surface of the golf club head I before the layer 5 or the outer layer 6 is applied. The base layer 7 may be nickel or a nickel alloy that is applied to the exterior surface of the golf club head 1, or some portion of the exterior surface of the golf club head 1, by electroplating, non-PVD sputtering, or physical vapor deposition (“PVD”), or another coating process that allows for the adherence of the base layer 7 to the exterior surface of the golf club head 1. The base layer 7 provides, for example, additional rust protection for the golf club head 1 in addition to the use of martensitic stainless steel for the golf club head 1, or portions thereof.

According to the aspect illustrated in FIG. 3, layer 5 may be applied to all or part of the exterior surface (which, according to this example, has been at least partially coated by base layer 7) of the golf club head 1. The layer 5 may be chromium or a chromium alloy that is applied to the exterior surface of the golf club head 1, or some portion of the exterior surface of the golf club head 1, by electroplating, non-PVD sputtering, or physical vapor deposition (“PVD”), or another coating process that allows for the adherence of the layer 5 to the exterior surface of the golf club head 1 or portion(s) of the golf club head 1 coated with the base layer 7. For example, the layer 5 may be applied to the entire exterior surface of the golf club head 1, the entire portion of the golf club head 1 that is coated with the base layer 7, only a portion of the golf club head 1 that is coated with the base layer 7, and/or a portion of the exterior surface of the golf club head 1 that is not coated with the base layer 7. The layer 5 may be deposited on only the bottom portion 9 of the golf club head 1, or on only a part of the bottom portion 9, that is designed to contact the ground 12 during use of a golf club including the golf club head.

According to the aspect of FIG. 3, the outer layer 6 may be applied to all or part of the golf club head 1. For example, the outer layer 6 may be applied to the entire exterior surface of the golf club head 1, the entire portion of the golf club head I, that is coated with layer 5 and/or base layer 7, a portion of the golf club head 1 that is coated with layer 5 and/or base layer 7, and/or a portion of the exterior surface of the golf club head 1 that is not coated with layer 5 and/or base layer 7. The outer layer 6 may be applied by electroplating or non-PVD sputtering. Preferably, however, the outer layer 6 is applied by PVD.

Like the embodiment of FIG. 2, when the outer layer 6 is abraded, scratched, and/or nicked due to contact with the ground, the layer 5 is exposed. The exposure of layer 5 in the portions of the outer layer 6 that have been nicked, scratched, and/or abraded reduces the appearance of the nicks, scratches, and/or abrasions, or alternatively provides for a shinier appearance of the nicks, scratches, and/or abrasions, which in either case enhances a golfer's confidence in the golf club head's performance, durability, and appearance.

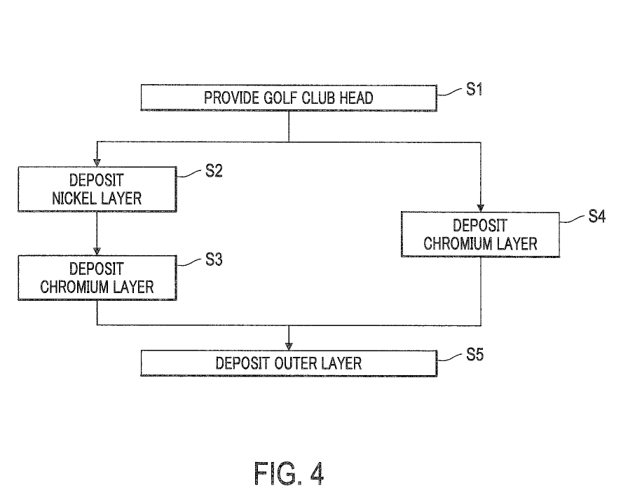

FIG. 4 illustrates an exemplary process of coating the golf club head 1 with the layered coatings, as illustrated in FIGS. 2 and 3. As shown, by way of example, in FIG. 4, a golf club head formed of a base material is provided (step Si). The base material is at least partially composed of martensitic stainless steel. If additional rust protection is deemed necessary or desired, a base nickel or nickel alloy layer is applied to all or part of the golf club head (step S2). However, such step is preferably omitted to reduce production costs. All or part of the golf club head is then coated with a chromium layer (step S3). If additional rust protection is deemed unnecessary or undesired, for example, if the portions of the golf club head subject to the possibility of rusting are sufficiently composed of martensitic stainless steel, only the chromium layer is applied to all or part of the golf club head (step S4). Then, after the chromium layer is applied (in either step S3 or S4), an outer layer including a metal and a nonmetal is applied to all or part of the golf club head (step S5), preferably by physical vapor deposition.

As a result of the process, as discussed above, the layer of chromium under the outer layer has the unexpected effect of making any scratches, nicks, or abrasions less visible to a golfer. Further, when large areas of chromium become exposed, it has been determined that the reflective nature of the exposed chromium leaves the golfer with the impression of quality materials compared to exposed less reflective materials such as steel, titanium, or nickel. The perception of use of quality materials inspires confidence in the golfer. Furthermore, by using martensitic stainless steel as a base material, the process does not require the use of a nickel or nickel alloy coating layer. By avoiding the use of a nickel or nickel alloy coating layer, the cost and complexity of producing the golf club head are reduced while maintaining all of the desired features of the golf club head.

Those skilled in the art will appreciate that while the present invention has been described in association with presently preferred aspects thereof, numerous changes, modifications, and substitutions of equivalents may be made therein without departing from the spirit and scope of this invention, which is intended to be unlimited by the foregoing except as may appear in the following appended claims.

What is claimed is:

1. A method of manufacturing a golf club head, the method comprising:
providing a golf club head main body at least partially composed of martensitic stainless steel and having an exterior surface;
depositing at least one chromium layer on at least a portion of the exterior surface of the main body; and
physical vapor depositing at least one outer layer on at least a portion of the at least one chromium layer, the outer layer comprising a metal and a nonmetal.

2. The method of claim 1, wherein the metal is selected from the group consisting of vanadium, chromium, zirconium, titanium, niobium, molybdenum, hafnium, tantalum, and tungsten, and the nonmetal is selected from the group consisting of a nitride, a carbide, and a carbonitride.

3. The method of claim 1, further comprising:
electroplating the at least one chromium layer.

4. The method of claim 1, further comprising:
sputtering the at least one chromium layer.

5. The method of claim 1, further comprising:
physical vapor depositing the at least one chromium layer.

6. The method of claim 1, wherein the golf club head has a volume greater than or equal to about 80 cm³.

7. The method of claim 6, further comprising:
depositing at least one nickel layer on the exterior surface of the golf club head underneath at least a portion of the at least one chromium layer.

8. The method of claim 1, wherein the golf club head has a volume greater than or equal to about 120 cm³.

9. The method of claim 1, wherein the golf club head has a volume greater than or equal to about 120 cm³ but less than or equal to about 220 cm³.

10. The method of claim 1, wherein the exterior surface of the golf club head includes a top portion and a bottom portion, and the at least one chromium layer is deposited on only the bottom portion of the exterior surface.

11. The method of claim 10, wherein the at least one chromium layer is deposited on only a part of the bottom portion that is designed to contact the ground during use of a golf club including the golf club head.

12. The method of claim 1, wherein the at least one outer layer is deposited on only the at least one chromium layer.

13. The method of claim 1, wherein the at least one outer layer comprises at least one of titanium nitride and titanium carbide.

14. The method of claim 1, further comprising:
selecting the metal and the nonmetal such that the outer layer is a predetermined color selected from the group consisting of black, silver, gray, blue, gold, purple, bronze, white, red, pink, and green.

15. The method of claim 1, wherein the golf club head is hollow.

16. The method of claim 1, wherein the golf club head further includes a loft angle no greater than 22 degrees.

17. The method of claim 1, wherein the martensitic stainless steel has a chromium content no less than 14% by mass.

18. A golf club head comprising:
a main body at least partially composed of martensitic stainless steel and having an exterior surface;
at least one chromium layer on at least a portion of the exterior surface; and
at least one physical-vapor-deposited outer layer on at least a portion of the at least one chromium layer, the at least one outer layer comprising a metal and a nonmetal.

19. The golf club head of claim 18, wherein the metal is selected from the group consisting of vanadium, chromium, zirconium, titanium, niobium, molybdenum, hafnium, tantalum, and tungsten, and the nonmetal is selected from the group consisting of a nitride, a carbide, and a carbonitride.

20. The golf club head of claim 18, wherein the at least one chromium layer has a structure resulting from the at least one chromium layer being deposited by physical vapor deposition.

21. The golf club head of claim 18, wherein the at least one chromium layer has a structure resulting from the at least one chromium layer being deposited by electroplating.

22. The golf club head of claim 18, wherein the at least one chromium layer has a structure resulting from the at least one chromium layer being deposited by sputtering.

23. The golf club head of claim 18, wherein the main body has a volume greater than or equal to about 80 cm³.

24. The golf club head of claim 23, further comprising:
depositing at least one nickel layer on the exterior surface of the golf club head underneath at least a portion of the at least one chromium layer.

25. The golf club head of claim 18, wherein the main body has a volume greater than or equal to about 120 cm³.

26. The golf club head of claim 18, wherein the main body has a volume greater than or equal to about 120 cm³ but less than or equal to about 220 cm³.

27. The golf club head of claim 18, wherein:
the exterior surface of the golf club head includes a top portion and a bottom portion; and
the at least one chromium layer is on only the bottom portion of the exterior surface.

28. The golf club head of claim 27, wherein the at least one chromium layer is on only a part of the bottom portion that is designed to contact the ground during use of a golf club including the golf club head.

29. The golf club head of claim 18, wherein the at least one outer layer is on only the at least one chromium layer.

30. The golf club head of claim 18, wherein the at least one outer layer comprises at least one of titanium nitride and titanium carbide.

31. The golf club head of claim 18, wherein the metal and the nonmetal are selected such that the outer layer is a predetermined color selected from the group consisting of black, silver, gray, blue, gold, purple, bronze, white, red, pink, and green.

32. The golf club head of claim 18, wherein the golf club head is hollow.

33. The golf club head of claim 18, further including a loft angle no greater than 22 degrees.

34. The golf club head of claim 18, wherein the martensitic stainless steel has a chromium content no less than 14% by mass.

35. A golf club head comprising:
a main body at least partially composed of martensitic stainless steel and having an exterior surface;
at least one physical-vapor-deposited chromium layer on at least a portion of the exterior surface corresponding to a portion of the golf club head that is designed to contact the ground during use of a golf club including the golf club head; and
at least one physical-vapor-deposited outer layer on at least a portion of the at least one chromium layer, the at least one outer layer comprising at least one of titanium nitride and titanium carbide,
wherein the golf club head has a volume greater than or equal to about 120 cm³ but less than or equal to about 220 cm³.

36. A golf club head comprising:
a main body at least partially composed of stainless steel having a chromium content no less than 14% by mass and having an exterior surface;
at least one chromium layer on at least a portion of the exterior surface; and
at least one physical-vapor-deposited outer layer on at least a portion of the at least one chromium layer, the at least one outer layer comprising a metal and a nonmetal.

37. The golf club head of claim 36, wherein the metal is selected from the group consisting of vanadium, chromium, zirconium, titanium, niobium, molybdenum, hafnium, tantalum, and tungsten, and the nonmetal is selected from the group consisting of a nitride, a carbide, and a carbonitride.

38. The golf club head of claim 36, wherein the at least one chromium layer has a structure resulting from the at least one chromium layer being deposited by physical vapor deposition.

39. The golf club head of claim 36, wherein the main body has a volume greater than or equal to about 80 cm³.

40. The golf club head of claim 36, wherein the main body has a volume greater than or equal to about 120 cm³.

41. The golf club head of claim 36, wherein:
the exterior surface of the golf club head includes a top portion and a bottom portion; and
the at least one chromium layer is on only the bottom portion of the exterior surface.

42. The golf club head of claim 36, wherein the at least one outer layer comprises at least one of titanium nitride and titanium carbide.

43. The golf club head of claim 36, further including a loft angle no greater than 22 degrees.

44. A golf club head comprising:
a main body composed entirely of a homogenous rust-resistant material and having an exterior surface;
at least one chromium layer on at least a portion of the exterior surface; and
at least one physical-vapor-deposited outer layer on at least a portion of the at least one chromium layer, the at least one outer layer comprising a metal and a nonmetal.

45. The golf club head of claim 44, wherein the metal is selected from the group consisting of vanadium, chromium, zirconium, titanium, niobium, molybdenum, hafnium, tantalum, and tungsten, and the nonmetal is selected from the group consisting of a nitride, a carbide, and a carbonitride.

46. The golf club head of claim 44, wherein the at least one chromium layer has a structure resulting from the at least one chromium layer being deposited by physical vapor deposition.

47. The golf club head of claim 44, wherein the main body has a volume greater than or equal to about 80 cm³.

48. The golf club head of claim 44, wherein:
the exterior surface of the golf club head includes a top portion and a bottom portion; and
the at least one chromium layer is on only the bottom portion of the exterior surface.

49. The golf club head of claim 44, wherein the at least one outer layer comprises at least one of titanium nitride and titanium carbide.

50. The golf club head of claim 44, further including a loft angle no greater than 22 degrees.
